(19) United States
(12) Patent Application Publication
(10) Pub. No.: US 2020/0312739 A1
(43) Pub. Date: Oct. 1, 2020

(54) SEMICONDUCTOR DEVICE AND METHOD FOR MANUFACTURING SAME

(71) Applicant: TOYOTA JIDOSHA KABUSHIKI KAISHA, Toyota-shi (JP)

(72) Inventor: Norimune ORIMOTO, Toyota-shi (JP)

(73) Assignee: TOYOTA JIDOSHA KABUSHIKI KAISHA, Toyota-shi (JP)

(21) Appl. No.: 16/781,378

(22) Filed: Feb. 4, 2020

(30) Foreign Application Priority Data
Mar. 25, 2019 (JP) 2019- 056878

(51) Int. Cl. H01L 23/373; H01L 23/492; H01L 25/07; H01L 25/00; H01L 21/56

(52) U.S. Cl. CPC H01L 23/3733; H01L 23/492; H01L 21/56; H01L 25/50; H01L 25/072

(57) ABSTRACT

A semiconductor device may include: a metal plate including a first surface and a second surface opposite to the first surface; two semiconductor chips bonded to the first surface side by side; a thermally anisotropic member provided at the metal plate between the two semiconductor chips; and a cooler provided on the second surface of the metal plate. A thermal conductivity of the thermally anisotropic member in a side-by-side direction of the two semiconductor chips may be lower than a thermal conductivity of the metal plate, and the thermal conductivity of the thermally anisotropic member in in-plane directions perpendicular to the side-by-side direction may be higher than the thermal conductivity of the metal plate.

### CROSS-REFERENCE

This application claims priority to Japanese Patent Application No. 2019-056878 filed on Mar. 25, 2019, the contents of which are hereby incorporated by reference into the present application.

The technology disclosed herein relates to a semiconductor device and a method of manufacturing the same. In particular, the technology relates to a semiconductor device in which two semiconductor chips are bonded to a metal plate.

### BACKGROUND

Japanese Patent Application Publication No. 2017-11021 describes a semiconductor device in which two semiconductor chips are bonded to a metal plate side by side. The metal plate is provided in order to dissipate heat of the semiconductor chips. However, a portion of the metal plate between the two semiconductor chips tends to have a high temperature because the heat of the both semiconductor chips concentrate to the portion. The metal plate of the semiconductor device of Japanese Patent Application Publication No. 2017-11021 is provided with a groove at the portion thereof between the two semiconductor chips. When the metal plate is viewed in its normal direction, the groove separates the two semiconductor chips. A high thermal resistance of the groove (air in the groove) suppresses the heat concentration of the two semiconductor chips.

The metal plate of the semiconductor device of Japanese Patent Application Publication No. 2017-11021 may be provided with a plurality of grooves in the portion thereof between the two semiconductor chips. The closer the grooves located to the semiconductor chips, the smaller their depths are. The deep grooves have a high thermal resistance, thus they suppress the heat concentration of the two semiconductor chips. The shallow grooves have a smaller thermal resistance than the deep grooves, but the metal below the shallow grooves contributes to heat dissipation of the semiconductor chips. The combination of the deep and shallow grooves can dissipate the heat of the semiconductor chips as well as suppress the heat concentration to the portion of the metal plate between the semiconductor chips.

### SUMMARY

The disclosure herein provides a technique that is able to achieve a better dissipation of heat of two semiconductor chips than the semiconductor device of Japanese Patent Application Publication No. 2017-11021 and suppress heat concentration to a portion between the two semiconductor chips located adjacent to each other.

A semiconductor device disclosed herein may comprise: a metal plate including a first surface and a second surface opposite to the first surface; two semiconductor chips bonded to the a first surface side by side; a thermally anisotropic member provided at the metal plate between the two semiconductor chips; and a cooler provided on the second surface of the metal plate. A thermal conductivity of the thermally anisotropic member in a side-by-side direction of the two semiconductor chips may be lower than a thermal conductivity of the metal plate, and the thermal conductivity of the thermally anisotropic member in in-plane directions perpendicular to the side-by-side direction may be higher than the thermal conductivity of the metal plate.

In the semiconductor device disclosed herein, the thermal conductivity of the thermally anisotropic member in the side-by-side direction is low. Therefore, concentration of heat of the two semiconductor chips can be suppressed. Although the thermal conductivity is low, the heat of the semiconductor chips gradually transfers to the thermally anisotropic member. Here, the thermal conductivity of the thermally anisotropic member in the in-plane directions perpendicular to the side-by-side direction is higher than the thermal conductivity of the metal plate. Therefore, the heat is spread in the in-plane directions (in-plane directions perpendicular to the side-by-side direction) in the thermally anisotropic member faster than transferring in the metal plate, and then is absorbed by the cooler. This helps suppression of concentration of the heat of the two semiconductor chips as well as transfer of the heat of the semiconductor chips to the cooler. The semiconductor device disclosed herein is excellent in dissipating the heat of the semiconductor chips and in suppressing the concentration of heat of the two semiconductor chips located side by side.

The present disclosure also provides a manufacturing method suitable for the above-described semiconductor device. The manufacturing method may comprise: providing a groove in a first surface of a metal plate; fitting a thermally anisotropic member into the groove; bonding two semiconductor chips to the first surface of the metal plate side by side such that the thermally anisotropic member is located between the two semiconductor chips; forming a resin package such that the resin package covers the two semiconductor chips and is bonded to the metal plate; and attaching a cooler to a second surface of the metal plate opposite to the first surface. The thermally anisotropic member may be fitted into the groove such that: a thermal conductivity of the thermally anisotropic member in a side-by-side direction of the two semiconductor chips is lower than a thermal conductivity of the metal plate; and the thermal conductivity of the thermally anisotropic member in in-plane directions perpendicular to a side-by-side direction is higher than the thermal conductivity of the metal plate.

Details and further improvements of the technique disclosed herein are described in “DETAILED DESCRIPTION” below.

### BRIEF DESCRIPTION OF DRAWINGS

FIG. 1 is a perspective view of a semiconductor device of a first embodiment.

FIG. 2 is a perspective view of a metal plate and a thermally anisotropic member.

FIG. 3 is a cross-sectional view along a line III-III in FIG. 1.

FIG. 4 is a perspective view of a semiconductor device of a second embodiment.

FIG. 5 is a perspective view of a semiconductor device of a third embodiment.

FIG. 6 is a perspective view of a semiconductor device of a fourth embodiment.

FIG. 7 is a cross-sectional view along a line VII-VII in FIG. 6.

FIG. 8 is a cross-sectional view of a semiconductor device of a fifth embodiment.

FIG. 9 is a cross-sectional view of a semiconductor device of a sixth embodiment.

FIG. 10 is a cross-sectional view of a semiconductor device of a seventh embodiment.

FIG. 11 is a cross-sectional view of a semiconductor device of an eighth embodiment.

FIG. 12 illustrates a process of a method of manufacturing a semiconductor device.

FIG. 13 illustrates a process following FIG. 12.

FIG. 14 illustrates a process following FIG. 13.

### EMBODIMENTS

### First Embodiment

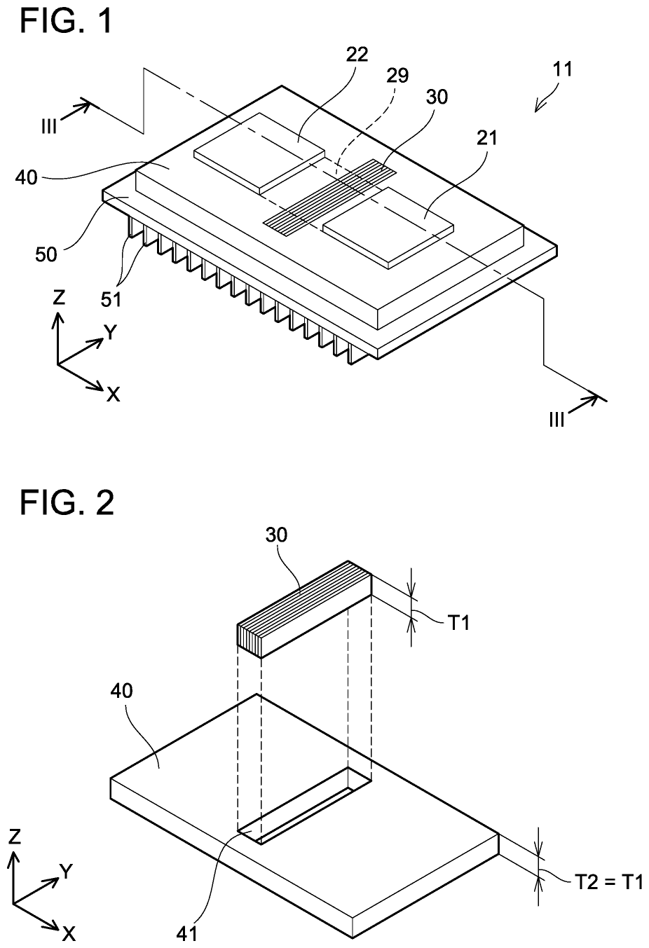

A semiconductor device 11 of a first embodiment will be described with reference to the drawings. FIG. 1 is a perspective view of the semiconductor device 11. The semiconductor device 11 includes two semiconductor chips 21 and 22. The semiconductor chips 21 and 22 each are a device in which an Insulated Gate Bipolar Transistor (IGBT) is formed. The semiconductor chips 21 and 22 are bonded to an upper surface of a metal plate 40 (a chip-side surface) side by side. A gap 29 is provided between the adjacent semiconductor chips 21 and 22, and the metal plate 40 is exposed at the gap 29. The semiconductor chips 21 and 22 are bonded to the metal plate 40 by solder. Each of the semiconductor chips has a flat-plate shape, has an emitter electrode provided on one wide surface thereof (an upper surface thereof in the drawing), and has a collector electrode provided on another wide surface thereof (a lower surface thereof in the drawing). The collector electrodes of both the semiconductor chips 21 and 22 are bonded to the metal plate 40. Another metal plate bonded to the emitter electrodes is not shown. Gate electrodes of the semiconductor chips 21 and 22 and terminals connected thereto are also not shown. Electrically, the two semiconductor chips 21 and 22 are connected in parallel by the two metal plates.

A coordinate system in the drawings will be described. An X direction coincides with a side-by-side direction of the two semiconductor chips 21 and 22. The side-by-side direction of the two semiconductor chips 21 and 22 may be hereinafter simply referred to as “side-by-side direction”. A Z direction coincides with a thickness direction of the metal plate 40, and may be simply referred to as “thickness direction” hereinafter. A Y direction of the coordinate system in the drawings may be hereinafter referred to as “longitudinal direction”. The side-by-side direction, the longitudinal direction, and the thickness direction are perpendicular to each other. A plane perpendicular to the X direction in the coordinate system in the drawings may be referred to as “perpendicular plane”. It may be also referred to as “sheet plane” for the reasons described later.

A cooler 50 is attached to a lower surface of the metal plate 40 (a cooler-side surface). The cooler 50 is a metal plate provided with a plurality of fins 51. The fins 51 may be exposed to cooling air, cooling liquid or the like. The cooler 50 is attached to a heat dissipation surface of the metal plate 40. As will be described later, a grease and an insulating plate may be interposed between the metal plate 40 and the cooler 50. The grease reduces a thermal resistance between the metal plate 40 and the cooler 50. The insulating plate insulates the metal plate 40 from the cooler 50.

The semiconductor chips 21 and 22 are switching elements used for power conversion and generate a large amount of heat during their operation. The cooler 50 absorbs the heat from the semiconductor chips 21, 22 through the metal plate 40. The absorbed heat is dissipated to the cooling liquid or the like through the plurality of fins 51.

FIG. 2 is a perspective view of the metal plate 40. As shown in FIG. 2, the metal plate 40 is provided with a rectangular through hole 41 when viewed in the thickness direction. The through hole 41 is open at both the chip-side surface and the heat dissipation surface, and penetrates the metal plate 40. A thermally anisotropic member 30 is fitted in the through hole 41. A thickness T1 of the thermally anisotropic member 30 is the same as a thickness T2 of the metal plate 40. That is, a chip-side surface of the thermally anisotropic member 30 is flush with the chip-side surface of the metal plate 40, and a heat dissipation surface of the thermally anisotropic member 30 is flush with the heat dissipation surface of the metal plate 40.

In the present embodiment, a graphene laminate in which a plurality of thin graphene sheets is laminated is used as the thermally anisotropic member 30. The graphene laminate has a high thermal conductivity in a direction along surfaces of the graphene sheets, while it has a low thermal conductivity in a laminate direction along which the graphene sheets are laminated. The graphene laminate possesses anisotropy in thermal conductivity. In this embodiment, the graphene laminate is used in an orientation where the laminate direction of the graphene laminate coincides with the side-by-side direction (X direction), and surfaces of the graphene sheets are perpendicular to the side-by-side direction (X direction).

The graphene laminate has a thermal conductivity of 1700 [W/mK] in its sheet in-plane directions and a thermal conductivity of 7 [W/mK] in the laminate direction. The metal plate 40 is constituted of, for example, copper, and has a thermal conductivity of 385 [W/mK]. The graphene laminate is used in the orientation where the lamination direction coincides with the side-by-side direction (X direction) and the sheet in-plane directions are perpendicular to the side-by-side direction (X direction). The thermal conductivity of the graphene laminate in the side-by-side direction (X direction) is much lower than that of the metal plate 40, and the former is 1/50 or less of the latter. The thermal conductivity of the graphene laminate in the directions perpendicular to the side-by-side direction (X direction) is much higher than that of the metal plate 40, and the former is 4 times or more higher than the latter.

The thermally anisotropic member 30 is attached to the metal plate 40 so as to be positioned at the gap 29 provided between the two semiconductor chips 21, 22. When viewed in the thickness direction (Z direction) of the metal plate 40, the thermally anisotropic member 30 extends so as to separate the two semiconductor chips 21 and 22. A length of the thermally anisotropic member 30 in the longitudinal direction is longer than a length of the gap 29 in the longitudinal direction, and the thermally anisotropic member 30 extends outwardly beyond the gap 29 in the longitudinal direction.

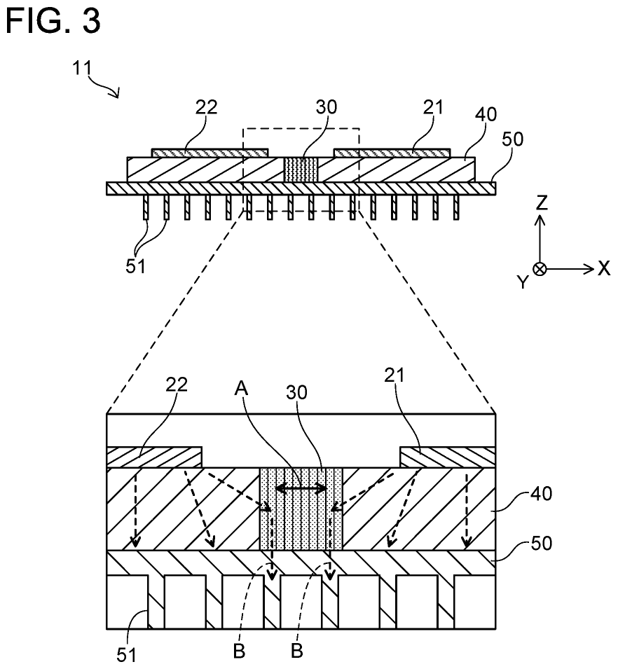

A cross section along a line III-III in FIG. 1 is shown in FIG. 3. The lower diagram of FIG. 3 is an enlarged view of a range indicated by the broken line in the upper diagram. Advantages of the thermally anisotropic member 30 will be described with reference to FIG. 3.

As described above, the semiconductor chips 21 and 22 are for power conversion and generate a large amount of heat during their operation. Therefore, the semiconductor device 11 includes the cooler 50 for cooling the semiconductor chips 21 and 22. The heat of the semiconductor chips 21 and 22 is transferred to the cooler 50 through the metal plate 40. The heat from the two semiconductor chips 21 and 22 concentrates to a portion of the metal plate 40 between the two semiconductor chips 21 and 22. When the heat from both the semiconductor chips 21 and 22 merges, a center of the metal plate 40 (a portion under the gap 29 between the two semiconductor chips 21, 22) is likely to have a locally high temperature. Therefore, the thermally anisotropic member 30 is disposed between the two semiconductor chips 21 and 22 to suppress the concentration of heat.

Dotted arrow lines in the lower diagram of FIG. 3 indicate heat transfer directions. The heat reaches the cooler 50 through the metal plate 40. The cooler 50 includes the plurality of fins 51, and the heat dissipates from surfaces of the fins 51.

The thermally anisotropic member 30 is disposed at the portion between the semiconductor chips 21 and 22. The thermal conductivity of the thermally anisotropic member 30 in the side-by-side direction (X direction) is lower than that of the metal plate 40. The heat may transfer slowly in a direction indicated by an arrow A in the lower diagram of FIG. 3. Therefore, the concentration of heat is suppressed.

Although the thermal conductivity in the side-by-side direction is low, the heat of the semiconductor chips 21 and 22 propagates into the thermally anisotropic member 30. The thermal conductivity of the thermally anisotropic member 30 in the thickness direction (Z direction) is higher than that of the metal plate 40. Therefore, the heat that reaches the thermally anisotropic member 30 is quickly transferred toward the cooler 50 and is absorbed by the cooler 50 (broken line arrows B in FIG. 3). This suppresses the concentration of heat of both the semiconductor chips 21 and 22 as well as contributes to the rapid absorption of the heat by the cooler 50. As shown in the lower diagram of FIG. 3, a lower surface of the thermally anisotropic member 30 is in contact with the cooler 50. This lower surface is located at an end of thermal path utilizing the high thermal conductivity in the thickness direction (Z direction). This also facilitates the transfer of heat from the thermally anisotropic member 30 to the cooler 50.

### Second Embodiment

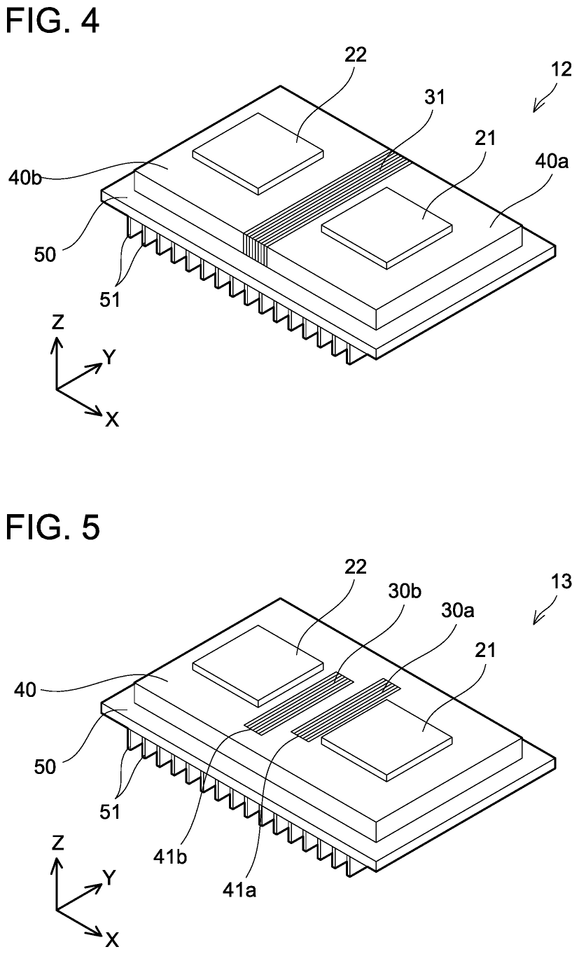

FIG. 4 is a perspective view of a semiconductor device 12 of a second embodiment. In the semiconductor device 12 of the second embodiment, the metal plate is divided into two, namely, into 40a and 40b. A thermally anisotropic member 31 is located between the two metal plates 40a and 40b. The thermally anisotropic member 31 reaches ends of the metal plates 40a and 40b in the longitudinal direction (Y direction). In the semiconductor device 12, the thermally anisotropic member 31 is long in the longitudinal direction (Y direction), thus heat is well dissipated in the longitudinal direction (Y direction). Instead, since the metal plate is divided into two in the semiconductor device 12, the strength of the semiconductor device 12 may be decreased. The semiconductor device 11 of the first embodiment has a greater strength than the semiconductor device 12 of the second embodiment because the metal plate 40 is continuous on both sides of the thermally anisotropic member 30 in the longitudinal direction (Y direction).

### Third Embodiment

FIG. 5 is a perspective view of a semiconductor device 13 of a third embodiment. The semiconductor device 13 includes two thermally anisotropic members 30a and 30b between the two semiconductor chips 21 and 22. The thermally anisotropic members 30a and 30b are long in the longitudinal direction (Y direction) and short in the side-by-side direction (X direction). The metal plate 40 is provided with two through holes 41a and 41b corresponding to the two thermally anisotropic members 30a and 30b. The size of each through hole 41a, 41b is smaller than that of the through hole 41 of the semiconductor device 11 of the first embodiment. Since the through holes are small, the semiconductor device 13 of the third embodiment has a greater strength than the semiconductor device 11 of the first embodiment. The thermally anisotropic members 30a, 30b are also constituted of graphene laminates. Since the through holes are small, the rigidity of the metal plate 40 is increased, and thus the metal plate 40 is less 6 deformed by stress applied in a manufacturing process of the semiconductor device. Therefore, the graphene laminates are less likely to be cracked.

### Fourth Embodiment

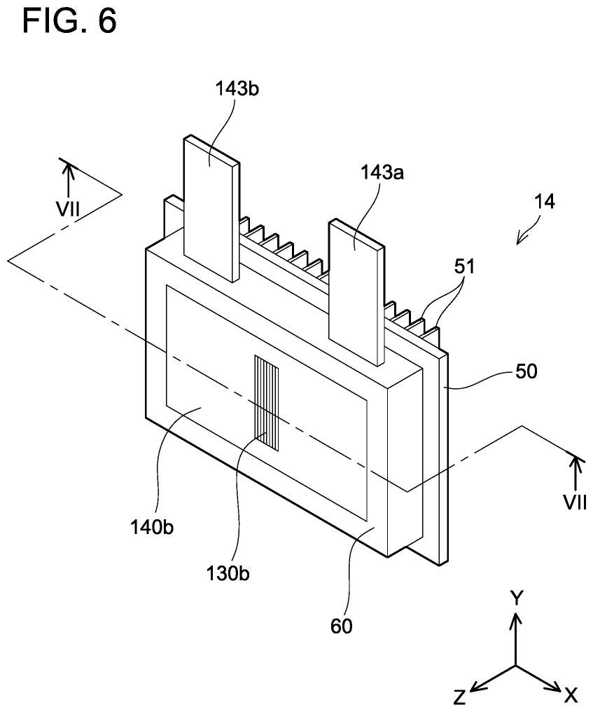

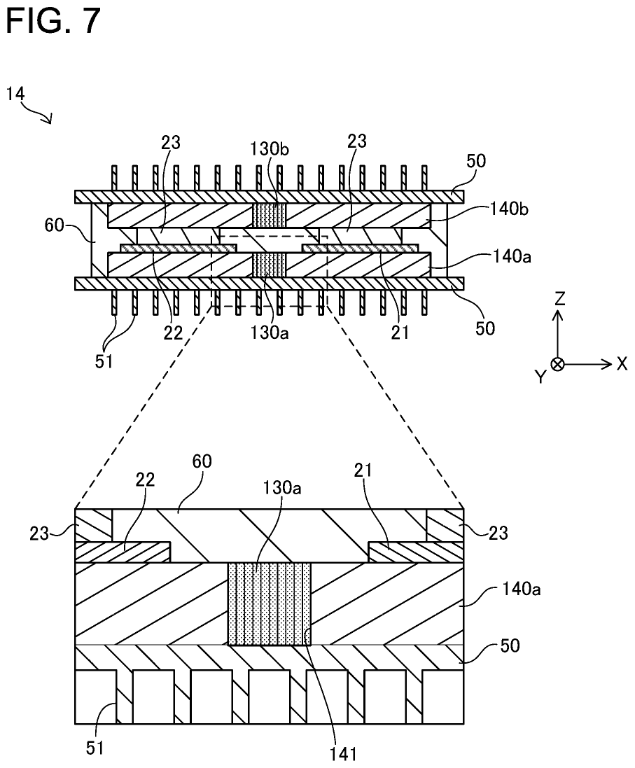

FIG. 6 is a perspective view of a semiconductor device 14 of a fourth embodiment. FIG. 7 shows a cross-sectional view along a line VII-VII in FIG. 6. The lower diagram of FIG. 7 is an enlarged view of a range indicated by the broken line in the upper diagram. As shown in FIG. 7, the two semiconductor chips 21 and 22 are bonded to an upper surface of a lower metal plate 140a (chip-side surface) side by side with a gap provided therebetween. Upper surfaces of the two semiconductor chips 21 and 22 are joined to a lower surface of an upper metal plate 140b via metal blocks 23. A gap is provided between the two metal blocks 23. In other words, the two semiconductor chips 21 and 22 are interposed between the lower metal plate 140a and the upper metal plate 140b. A material of the metal blocks 23 is, for example, copper.

The two semiconductor chips 21 and 22 are sealed in a resin package 60. The package 60 is in close contact with side surfaces of the two semiconductor chips 21 and 22, an upper surface of the lower metal plate 140a, and a lower surface of the upper metal plate 140b. The lower surface of the lower metal plate 140a and the upper surface of the upper metal plate 140b are exposed from the package 60, and the other surfaces thereof are in close contact with the package 60. The cooler 50 is attached to each of the lower surface of the lower metal plate 140a and the upper surface of the upper metal plate 140b. In FIG. 6, the cooler 50 attached to the upper metal plate 140b is not shown. The cooler 50 attached to the upper metal plate 140b is shown in FIG. 7.

Collector electrodes are provided on the lower surfaces of the semiconductor chips 21 and 22, and emitter electrodes are provided on the upper surfaces of the semiconductor chips 21 and 22. The lower metal plate 140a is electrically connected to the collector electrodes of the semiconductor chips 21 and 22, and the upper metal plate 140b is electrically connected to the emitter electrodes of the semiconductor chips 21 and 22 via the metal blocks 23. Electrically, the metal plates 140a and 140b connect the two semiconductor chips 21 and 22 in parallel. A terminal 143a extends from an edge of the lower metal plate 140a, and a terminal 143b extends from an edge of the upper metal plate 140b. As shown in FIG. 6, the terminals 143a, 143b extend outward from a narrow surface of the package 60. The terminals 143a and 143b correspond to positive and negative electrodes of the parallel connection of the two semiconductor chips 21 and 22.

The lower metal plate 140a is provided with a thermally anisotropic member 130a at a portion thereof between the two semiconductor chips 21 and 22. As shown in the lower diagram of FIG. 7, the metal plate 140a is provided with a through hole 141, and the thermally anisotropic member 130a is fitted in the through hole 141. The through hole 141 is open to a cooler 50 side and is also open to semiconductor chips 21 and 22 side. The through hole 141 penetrates the metal plate 140a. A thickness of the thermally anisotropic member 130a is equal to a thickness of the metal plate 140a, an upper surface of the thermally anisotropic member 130a is flush with the upper surface of the lower metal plate 140a, and a lower surface of the thermally anisotropic member 130a is flush with the lower surface of the lower metal plate 140a. The thermally anisotropic member 130a is in contact with the lower cooler 50.

The upper metal plate 140b is provided with a thermally anisotropic member 130b at a portion thereof between the two semiconductor chips 21 and 22 (portion between the two metal blocks 23). The upper metal plate 140b is also provided with a through hole, and this through 16 hole penetrates the upper metal plate 140b. The thermally anisotropic member 130b is fitted in the through hole. An upper surface of the thermally anisotropic member 130b is flush with the upper surface of the upper metal plate 140b, and a lower surface of the thermally anisotropic member 130b is flush with the lower surface of the upper metal plate 140b. The thermally anisotropic member 130b is in contact with the upper cooler 50.

A primer is applied on the surfaces of the metal plates 140a and 140b facing the package 60. The primer enhances the bonding strength between the metal plates 140a, 140b and the package 60.

A thermal conductivity of the thermally anisotropic member 130a in the side-by-side direction (X direction) is lower than that of the lower metal plate 140a, and the thermal conductivity thereof in the sheet in-plane (YZ plane) directions (the directions perpendicular to the side-by-side direction) is higher than that of the lower metal plate 140a. A thermal conductivity of the thermally anisotropy member 130b in the side-by-side direction (X direction) is lower than that of the upper metal plate 140b, and the thermal conductivity thereof in the sheet in-plane (YZ plane) directions (the directions perpendicular to the side-by-side direction) is higher than that of the upper metal plate 140b. In the semiconductor device 14 of the fourth embodiment, the concentration of heat to the portion between the two semiconductor chips 21 and 22 can be suppressed. Further, thermal stress generated at interfaces between the thermally anisotropic members 130a, 130b and the package 60 is also reduced. The fourth embodiment corresponds to an example in which a thermally anisotropic member is applied to each of a lower metal plate that is in contact with lower surfaces of semiconductor chips and an upper metal plate that is in contact with upper surfaces of the semiconductor chips via metal blocks. The thermally anisotropic member can be applied to one or both of the lower metal plate and the upper metal plate.

### Fifth Embodiment

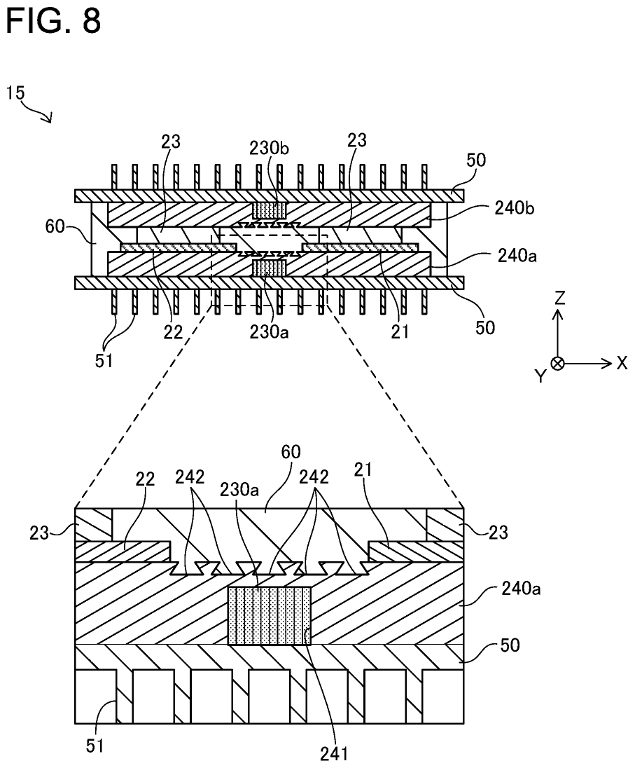

FIG. 8 is a cross-sectional view of a semiconductor device 15 of a fifth embodiment. The cross section of FIG. 8 corresponds to the cross section of FIG. 7. The lower diagram of FIG. 8 is an enlarged view of a range indicated by the broken line in the upper diagram of FIG. 8. The two semiconductor chips 21 and 22 are bonded to a metal plate 240a so as to be adjacent to each other with a gap provided therebetween. The semiconductor chips 21 and 22 are joined to a metal plate 240b via the metal blocks 23. A gap is provided between the two metal blocks 23. Between the metal plates 240a and 240b, side surfaces of the semiconductor chips 21 and 22 are covered by the resin package 60. The package 60 is also bonded to the metal plates 240a and 240b.

The metal plate 240a is provided with a groove 241. The groove 241 is located at a position corresponding to the gap between the two semiconductor chips 21 and 22. A thermally anisotropic member 230a is fitted in the groove 241. The groove 241 has an opening at a cooler 50 side, and the thermally anisotropic member 230a is in contact with the cooler 50 through the opening of the groove 241. The groove 241 is not open to semiconductor chips 21 and 22 side, and the metal plate 240a covers the thermally anisotropic member 230a at that side. In other words, the groove 241 is closed to the semiconductor chips 21 and 22 side. Since the groove 241 is not open to the semiconductor chips 21 and 22 side, the metal plate 240a has a great strength.

A thermal conductivity of the thermally anisotropic member 230a in the side-by-side direction is lower than that of the metal plate 240a, and the thermal conductivity thereof in the sheet in-plane directions is higher than that of the metal plate 240a.

A large number of other grooves 242 are provided in the metal plate 240a on the opposite side to the groove 241 (in a chip-side surface at the gap). These other grooves 242 are formed to gradually widen toward their bottoms. The resin of the package 60 is in the other grooves 242. Since the resin of the package 60 is in the other grooves 242, the package 60 is firmly coupled to the metal plate 240a by a wedge effect. The metal plate 240b is also provided with other grooves, similarly. The other grooves 242 may be widely provided in surfaces in contact with the package 60 (surfaces of the metal plates 240a, 240b), not only in the gap between the semiconductor chips 21, 22. The other grooves 242 may be a number of small depressions.

The structure with respect to the metal plate 240a and the thermally anisotropic member 230a is similarly applied to a structure with respect to the metal plate 240b and a thermally anisotropic member 230b. The thermally anisotropic members 230a and 230b have the same advantages as the thermally anisotropic member 30 of the first embodiment.

### Sixth Embodiment

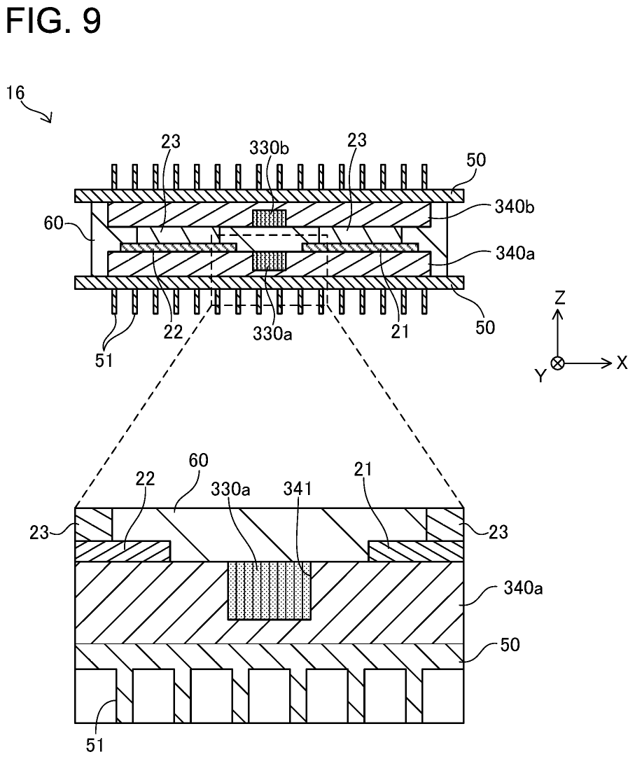

FIG. 9 is a cross-sectional view of a semiconductor device 16 of a sixth embodiment. The cross section of FIG. 9 corresponds to the cross section of FIG. 7. The lower diagram of FIG. 9 is an enlarged view of a range indicated by the broken line in the upper diagram of FIG. 9. The two semiconductor chips 21 and 22 are bonded to a metal plate 340a side-by-side with a gap provided therebetween. The semiconductor chips 21 and 22 are joined to a metal plate 340b via the metal blocks 23. Between the metal plates 340a and 340b, the side surfaces of the semiconductor chips 21 and 22 are covered by the resin package 60. The package 60 is also bonded to the metal plates 340a and 340b.

The metal plate 340a is provided with a groove 341. The groove 341 is provided to between the two semiconductor chips 21 and 22. A thermally anisotropic member 330a is fitted in the groove 341. The groove 341 has an opening at the semiconductor chips 21 and 22 side, and the thermally anisotropic member 330a is in contact with the package 60 through the opening of the groove 341. The groove 341 is not open to the cooler 50 side, and the metal plate 340a covers the thermally anisotropic member 330a at that side. In other words, groove 341 is closed to the cooler 50 side. Since the groove 341 is not open to the cooler 50 side, the metal plate 340a has a great strength.

A thermal conductivity of the thermally anisotropic member 330 in the side-by-side direction is lower than that of the metal plate 340a, and the thermal conductivity thereof in the sheet in-plane directions is higher than that of the metal plate 340a.

The structure with respect to the metal plate 340a and the thermally anisotropic member 330a is similarly applied to a structure with respect to the metal plate 340b and a thermally anisotropic member 330b. The thermally anisotropic members 330a and 330b have the same advantages as the thermally anisotropic member 30 of the first embodiment.

### Seventh Embodiment

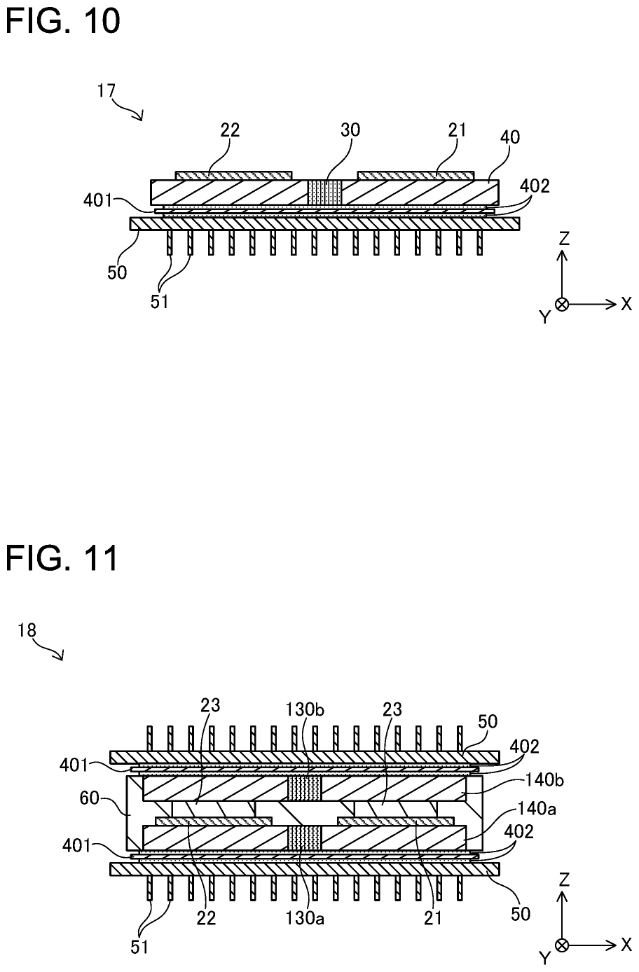

FIG. 10 is a cross-sectional view of a semiconductor device 17 of a seventh embodiment. The cross section of FIG. 10 corresponds to the cross section of FIG. 3. The semiconductor device 17 is a variant of the semiconductor device 11 of the first embodiment. Components of the semiconductor device 17 that are the same as those of the semiconductor device 11 (FIG. 3) are denoted with the same reference signs.

In the semiconductor device 17, an insulating plate 401 and a grease 402 are interposed between the metal plate 40 and the cooler 50. The grease 402 is interposed between the metal plate 40 and the insulating plate 401, and the grease 402 is interposed also between the cooler 50 and the insulating plate 401. The grease 402 is interposed also between the thermally anisotropic member 30 and the insulating plate 401. The insulating plate 401 insulates the metal plate 40 from the cooler 50. The grease 402 reduces a thermal resistance between the metal plate 40 (the thermally anisotropic member 30) and the cooler 50.

### Eighth Embodiment

FIG. 11 is a cross-sectional view of a semiconductor device 18 of an eighth embodiment. The cross section of FIG. 11 corresponds to the cross section of FIG. 7. The semiconductor device 18 is a variant of the semiconductor device 14 of the fourth embodiment. Components of the semiconductor device 18 that are the same as those of the 6 semiconductor device 14 (FIG. 7) are denoted with the same reference signs.

In the semiconductor device 18, the insulating plate 401 and the grease 402 are interposed between the metal plate 140a and the cooler 50. The grease 402 is interposed between the metal plate 140a and the insulating plate 401, and the grease 402 is interposed also between the cooler 50 and the insulating plate 401. The grease 402 is interposed also between the thermally 1o anisotropic member 130a and the insulating plate 401. The insulating plate 401 insulates the metal plate 140a from the cooler 50. The grease 402 reduces the thermal resistance between the metal plate 140a (the thermally anisotropic member 130a) and the cooler 50. Similarly, the insulating plate 401 and the grease 402 are interposed between the metal plate 140b (the thermally anisotropic member 130b) and the cooler 50, as well.

### Manufacturing Method

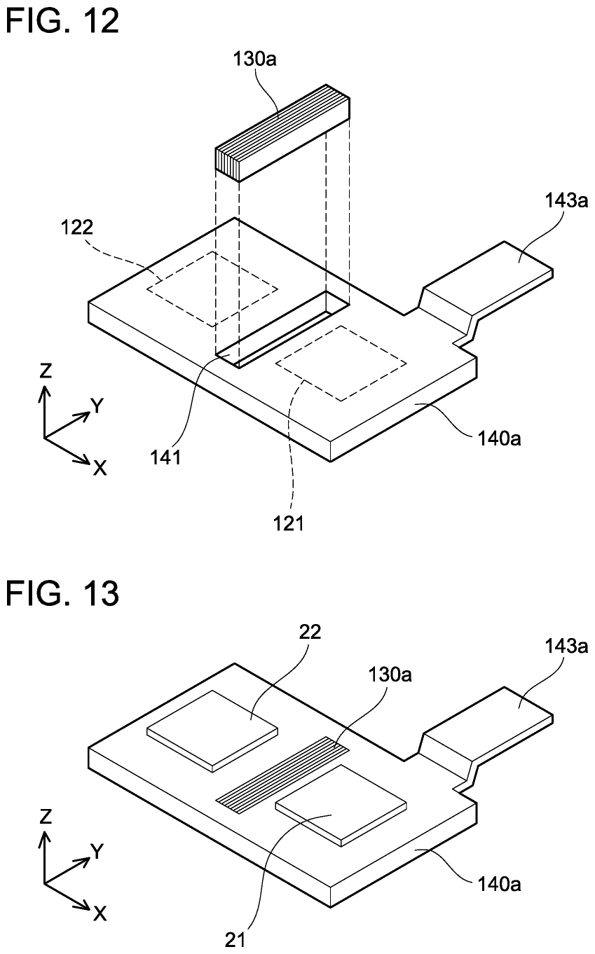

A method of manufacturing the semiconductor device 14 of FIG. 6 will be described with reference to FIGS. 12 to 14. First, the through hole 141 is provided in the metal plate 140a. Depending on embodiments, the groove 241 or the groove 341 is provided, in place of the through hole 141. Next, the thermally anisotropic member 130a is fitted into the through hole 141 (FIG. 12). The two semiconductor chips 21 and 22 are to be bonded to the metal plate 140a later, and broken lines 121 and 122 in FIG. 12 indicate the bonding positions of the two semiconductor chips. The thermally anisotropic member 130a is fitted into the through hole 141 in an orientation where its thermal conductivity in the side-by-side direction, which connects the bonding positions 122 and 122, is lower than its thermal conductivity in the Y direction and the Z direction.

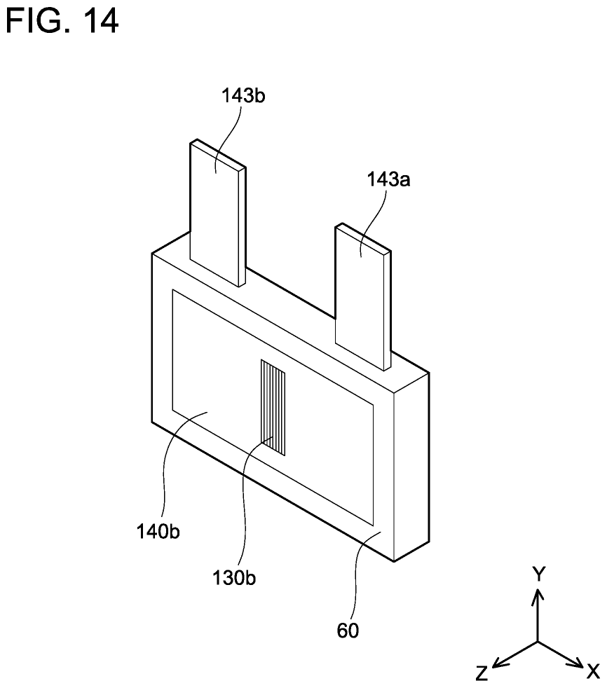

Next, the semiconductor chips 21 and 22 are bonded to the bonding positions 122 and 122 of the metal plate 140a. The semiconductor chips 21 and 22 are respectively bonded on both sides of the thermally anisotropic member 130a as viewed in the thickness direction (Z direction) of the metal plate 140a (FIG. 13). In other words, the semiconductor chips 21 and 22 are bonded to the metal plate 140a such that the thermally anisotropic member 130a is located between the semiconductor chips 21 and 22 as viewed in the thickness direction (Z direction). Solder is used for the bonding.

The thermally anisotropic member 130a is a laminate of graphene sheets. The thermally anisotropic member 130a is arranged such that the lamination direction of the graphene sheets coincides with the side-by-side direction (X direction). The thermal conductivity of the thermally anisotropic member 130a in the side-by-side direction (X direction) is lower than the thermal conductivity of the metal plate 140a. The thermal conductivity of the thermally anisotropic member 130a in the sheet in-plane directions (Y and Z directions) is higher than the thermal conductivity of the metal plate 140a.

The metal blocks 23 are bonded to the semiconductor chips 21 and 22 of FIG. 13, and the metal plate 140b is further bonded onto the metal blocks. The metal plate 140b has the same structure as the metal plate 140a, and is provided with the thermally anisotropic member 130b. The thermally anisotropic member 130b is arranged at a portion of the metal plate 140b between the two semiconductor chips 21 and 22. FIG. 7 should be referred to for the metal plate 140b and the thermally anisotropic member 130b.

Next, the resin package 60 is formed between the pair of metal plates 140a and 140b (FIG. 14). The package 60 is formed by insert molding. The package 60 is in close contact with the side surfaces of the two semiconductor chips 21 and 22, the upper surface of the metal plate 140a, and the lower surface of the metal plate 140b. Finally, the cooler 50 is attached to each of the metal plates 140a and 140b. The completed semiconductor device 14 is shown in FIG. 6. However, as described above, the cooler 50 attached to the metal plate 140b is not shown in FIG. 6.

Some of the features of the semiconductor devices described in the embodiments are listed below. The semiconductor devices 11 to 16 include at least two semiconductor chips 21 and 22, one or two metal plates 40 (140a-340a, 140b-340b), and one or two coolers 50. The two semiconductor chips are bonded to the chip-side surface of the metal plate such that they are positioned adjacent to each other with a gap provided therebetween. The cooler is attached to the surface (heat dissipation surface) of the metal plate opposite to the semiconductor chips. One or two thermally anisotropic members 30 (130a-330a, 130b-330b) are arranged in the one or more metal plates 40 (140a-340a, 140b-340b) at the position corresponding to the gap between the two semiconductor chips 21 and 22. The thermally anisotropic member(s) extends so as to separate the two semiconductor chips 21 and 22 when viewed in the thickness direction of the metal plate(s) 40. The thermal conductivity of the thermally anisotropic member(s) in the side-by-side direction is lower than the thermal conductivity of the metal plate(s) 40. The thermal conductivity of the thermally anisotropic member(s) in the longitudinal direction and the thickness direction is higher than the thermal conductivity of the metal plate(s) 40.

The metal plate 40 (140a, 140b, 240a, 240b) is provided with a recess 41 (141, 241) that is open to the cooler 50 side. The thermally anisotropic member 30 (130a, 130b, 230a, 230b) is accommodated in the recess 41 (141, 241).

The recess 41 (141) may penetrate the metal plate 40 (140a, 140b).

The thermally anisotropic member 30 (130a, 130b, 230a, 230) is in contact with the cooler 50. The insulating plate 401 and the grease 402 may be interposed between the metal plate 40 (the thermally anisotropic member 30) and the cooler 50. The insulating plate 401 insulates the metal plate 40 (the thermally anisotropic member 30) from the cooler 50. The grease 402 is interposed between the insulating plate 401 and the metal plate (the thermally anisotropic member 30), and the grease 402 is also interposed between the insulating plate 401 and the cooler 50. The grease 402 reduces the thermal resistance between the metal plate 40 (the thermally anisotropic member 30) and the cooler 50.

The metal plate 40 (140a, 140b, 340a, 340b) is provided with a recess 41 (141, 341) that is open to the semiconductor chips 21 and 22 side, and the thermally anisotropic member 30 (130a, 130b, 330a, 330b) is accommodated in the recess 41 (141, 341).

The semiconductor devices 12-16 include the metal plate 140a (240a, 340a) and another metal plate 140b (240b, 340b). The metal plate 140a (240a, 340a) is bonded to one surfaces of the semiconductor chips 21 and 22, and the other metal plate 140b (240b, 340b) is bonded to the other surfaces of the semiconductor chips 21 and 22 via the metal blocks. The other metal plate 140b (240b, 340b) is provided with another thermally anisotropic member 130b (230b, 330b) at the gap between the two semiconductor chips 21 and 22. The thermal conductivity of the other thermally anisotropic member 130b (230b, 330b) in the side-by-side direction is lower than that of the other metal plate 140b (240b, 340b). The thermal conductivity of the other thermally anisotropic member 130b (230b, 330b) in the longitudinal direction and the thickness direction is higher than that of the other metal plate 140b (240b, 340b).

The thermally anisotropic member 30 (130a-330a, 130b-330b) is constituted of graphene sheets. The thermally anisotropic member 30 (130a-330a, 130b-330b) is a lamination of graphene sheets. The lamination direction of the graphene sheets coincides with the side-by-side direction.

The semiconductor devices 14-16 further include the resin package 60 that covers the two semiconductor chips 21 and 22 and is bonded to the metal plates 140a and 140b (240a, 240b, 340a, 340b).

Some tips in the embodiments are described. The upper side surface (chip-side surface) of the metal plate (40, 40a, 40b, 140a, 240a, 340a) corresponds to a first surface of a metal plate (40, 40a, 40b, 140a, 240a, 340a). The lower side surface (cooler-side surface) of the metal plate (40, 40a, 40b, 140a, 240a, 340a) corresponds to a second surface of the metal plate (40, 40a, 40b, 140a, 240a, 340a).

While specific examples of the present disclosure have been described above in detail, these examples are merely illustrative and place no limitation on the scope of the patent claims. The technology described in the patent claims also encompasses various changes and modifications to the specific examples described above. The technical elements explained in the present description or drawings provide technical utility either independently or through various combinations. The present disclosure is not limited to the combinations described at the time the claims are filed. Further, the purpose of the examples illustrated by the present description or drawings is to satisfy multiple objectives simultaneously, and satisfying any one of those objectives gives technical utility to the present disclosure.

Although two semiconductor chips are used in the embodiments disclosed herein, three or more semiconductor chips may be used. For example, when a first semiconductor chip, a second semiconductor chip, and a third semiconductor chip are arranged in this order, the thermally anisotropic member may be arranged at one or both of a gap between the first semiconductor chip and the second semiconductor chip and a gap between the second semiconductor chip and the third semiconductor chip. Further, the cooler(s) is not necessarily required, and the heat radiation surface(s) of the metal plate(s) may be exposed to cooling air or cooling liquid. The metal plate(s) does not necessarily serves as an electrical conductive path, thus the technique disclosed herein is also effective for semiconductor devices in which an electrical conductive path is secured in addition to the metal plate for heat transfer.

The present technique is effective when a resin package is in close contact with a portion of metal plate that is exposed at a gap between two semiconductor chips. When the resin package is in close contact with the metal plate, the life of solder bonding the metal plate and the semiconductor chips can be extended. This technique can thus extend the life of the semiconductor device. However, the resin package is not necessarily required, and the present technique is also effective for semiconductor devices including no resin package.

What is claimed is:

1. A semiconductor device comprising:
a metal plate including a first surface and a second surface opposite to the first surface;
two semiconductor chips bonded to the first surface side by side;
a thermally anisotropic member provided at the metal plate between the two semiconductor chips; and
a cooler provided on the second surface of the metal plate,
wherein
a thermal conductivity of the thermally anisotropic member in a side-by-side direction of the two semiconductor chips is lower than a thermal conductivity of the metal plate, and
the thermal conductivity of the thermally anisotropic member in in-plane directions perpendicular to the side-by-side direction is higher than the thermal conductivity of the metal plate.

2. The semiconductor device according to claim 1, wherein
a groove is provided in the second surface of the metal plate, and
the thermally anisotropic member is fitted in the groove.

3. The semiconductor device according to claim 2, wherein the groove penetrates the metal plate to the first surface.

4. The semiconductor device according to claim 1, wherein a grease and an insulating plate are interposed between the metal plate and the cooler.

5. The semiconductor device according to claim 1, wherein the thermally anisotropic member is in contact with the cooler.

6. The semiconductor device according to claim 1, wherein a groove is provided in the first surface of the metal plate, and
the thermally anisotropic member is fitted in the groove.

7. The semiconductor device according to claim 1, further comprising:
an additional metal plate bonded to the two semiconductor chips on an opposite side to the metal plate; and
an additional thermally anisotropic member provided at the additional metal plate between the two semiconductor chips,
wherein
a thermal conductivity of the additional thermally anisotropic member in the side-by-side direction is lower than a thermal conductivity of the additional metal plate, and
the thermal conductivity of the additional thermally anisotropic member in the in-plane directions perpendicular to the side-by-side direction is higher than the thermal conductivity of the additional metal plate.

8. The semiconductor device according to claim 1, wherein the thermally anisotropic member is constituted of graphene.

9. The semiconductor device according to claim 1, further comprising a resin package covering the two semiconductor chips and bonded to the metal plate.

10. A manufacturing method of a semiconductor device comprising:
providing a groove in a first surface of a metal plate;
fitting a thermally anisotropic member into the groove;
bonding two semiconductor chips to the first surface of the metal plate side by side such that the thermally anisotropic member is located between the two semiconductor chips;
forming a resin package such that the resin package covers the two semiconductor chips and is bonded to the metal plate; and
attaching a cooler to a second surface of the metal plate opposite to the first surface,
wherein
the thermally anisotropic member is fitted into the groove such that:
a thermal conductivity of the thermally anisotropic member in a side-by-side direction of the two semiconductor chips is lower than a thermal conductivity of the metal plate, and
the thermal conductivity of the thermally anisotropic member in in-plane directions perpendicular to the side-by-side direction is higher than the thermal conductivity of the metal plate.
